(19) United States
(12) Patent Application Publication
(10) Pub. No.: US 2001/0040259 A1
(43) Pub. Date: Nov. 15, 2001

(54) Semiconductor device and method of manufacturing the same

(76) Inventors: Mika Shiiki, Chiba-shi (JP); Kenji Kitamura, Chiba-shi (JP)

Correspondence Address: ADAMS & WILKS, Attorneys And Counselors At Law, 50 Broadway, 31st Floor, New York, NY, 10004, US

(21) Appl. No.: 09/548,123

(22) Filed: Apr. 12, 2000

(30) Foreign Application Priority Data
Apr. 12, 1999 (JP) 11-104568

(51) Int. Cl. H01L 29/76; H01L 31/062

(52) U.S. Cl. 257/369; 438/199; 257/371; 438/223

(57) ABSTRACT

An objective of the present invention is to realize a comparator which uses MOS transistors and has a reduced offset voltage and occupies a small surface area. This is characterized in that an impurity is introduced into a channel region of a MOS transistor, the mobility of a load side MOS transistor is made smaller than the mobility of a differential side MOS transistor, and the mutual conductance of the load side MOS transistor is made smaller than the mutual conductance of the differential side MOS transistor.

### BACKGROUND OF THE INVENTION

1. Field of the Invention

The present invention relates to a semiconductor device and a method of manufacturing the same, and in particular the present invention relates to a comparator circuit using a MOS transistor.

2. Description of the Related Art

Comparators using MOS transistors have been widely used conventionally, and it is known that MOS transistors with an enlarged channel length and an enlarged channel width can be used in order to obtain a comparator with a small offset voltage.

However, a comparator using a conventional MOS transistor has a problem in that in order to use means for increasing the channel width and the channel length of the MOS transistor to make the offset voltage small, the amount of surface area occupied by the comparator becomes large.

### SUMMARY OF THE INVENTION

An object of the present invention is to provide a comparator occupying a small surface area with a small offset voltage, one which is impossible for a comparator using a conventional MOS transistor.

In order to achieve the above object, the present invention uses the following means.

(1) The mutual conductance of MOS transistors of the load side is made smaller than the mutual conductance of MOS transistors of the differential side in a comparator structured by MOS transistors.

(2) The mobility of the MOS transistors of the load side of the above comparator is made smaller than the mobility of those of the differential side.

(3) The impurity concentration in the channel region of the MOS transistors of the load side of the above comparator is made higher than the impurity concentration in the MOS transistors of the differential side.

(4) The threshold voltage of the MOS transistors of the load side of the above comparator is made higher than the threshold voltage of the MOS transistors of the differential side.

(5) The gate oxide film thickness of the MOS transistors of the load side of the above comparator is made thicker than the gate oxide film thickness of the MOS transistors of the differential side.

(6) The MOS transistors of the load side of the above comparator are made into p-type transistors, and the MOS transistors of the differential side are made into n-type transistors.

(7) The MOS transistors of the load side of the above comparator are made into n-type transistors, and the MOS transistors of the differential side are made into p-type transistors.

(8) The impurity introduced into the channel region of the above MOS transistors is phosphorous.

(9) The impurity introduced into the channel region of the above MOS transistors is arsenic.

(10) The impurity introduced into the channel region of the above MOS transistors is boron.

(11) The impurity introduced into the channel region of the above MOS transistors is BF₂.

(12) Two or more impurities are introduced into the channel region of the above MOS transistors.

(13) Only the MOS transistors of the load side of the comparator include a gate electrode that does not overlap with a source diffusion and a drain diffusion formed in a substrate.

(14) A second conducting type well region is formed in a first conducting type silicon semiconductor substrate, a MOS transistor of the load side is formed in the second conducting type well region, and a MOS transistor of the differential side is formed outside the second conducting type well region.

(15) A second conducting type well region is formed in a first conducting type silicon semiconductor substrate, a MOS transistor of the differential side is formed in the second conducting type well, and a MOS transistor of the load side is formed outside the second conducting type well region.

(16) A second conducting type well region and a third conducting type well region are formed in a first conducting type silicon semiconductor substrate, and differential side and load side MOS transistors are formed in each well.

(17) A method of manufacturing a semiconductor device in which a p-type transistor, which becomes a load transistor, and an n-type transistor, which becomes a differential transistor, formed in an n-type semiconductor region and in a p-type semiconductor region, respectively, on the surface of a semiconductor substrate, are integrated into a CMOS semiconductor device, the method comprising the steps of:

forming a gate insulating film on the surface of the semiconductor substrate;

forming a silicon thin film on the gate insulating film;

introducing an n-type impurity into the semiconductor region thin silicon thin film using an impurity diffusion furnace;

selectively etching the silicon thin film and of forming a gate electrode on the gate insulating film;

forming source and drain regions by ion injection of a p-type impurity into the surface of the n-type semiconductor region using the gate electrode as a mask;

forming source and drain regions by ion injection of the n-type impurity phosphorous into the surface of the p-type semiconductor region using the gate electrode as a mask; and

activating the source and drain regions by heat treatment at between 900 and 1050° C.

(18) A method of manufacturing a semiconductor device in which a p-type transistor, which becomes a load transistor, and an n-type transistor, which becomes a differential transistor, formed in an n-type semiconductor region and in a p-type semiconductor region, respectively, on the surface of a semiconductor substrate, are integrated into a CMOS semiconductor device, the method comprising the steps of:

forming a gate insulating film on the surface of the semiconductor substrate;

forming a channel doped region by ion injection of an impurity into the surface of the n-type semiconductor region;

forming a channel doped region by ion injection of an impurity into the surface of the p-type semiconductor region;

forming a silicon thin film on the gate insulating film;

introducing an n-type impurity into the semiconductor region thin silicon thin film using an impurity diffusion furnace;

selectively etching the silicon thin film and of forming a gate electrode on the gate insulating film;

forming source and drain regions by ion injection of a p-type impurity into the surface of the n-type semiconductor region using the gate electrode as a mask;

forming source and drain regions by ion injection of the n-type impurity phosphorous into the surface of the p-type semiconductor region using the gate electrode as a mask; and

activating the source and drain regions by heat treatment at between 900 and 1050° C.

(19) One mask is used to form an n-type well layer and a p-type well layer in a semiconductor substrate, in which the p-type well layer is formed after the n-type well layer is formed.

(20) A siliconoxide film and a silicon nitride film are formed in order on the semiconductor substrate;

the silicon nitride film is selectively removed by a photo mask process, prescribing a region for the n-well layer;

an n-type impurity is ion injected into the semiconductor substrate;

a silicon oxide film is formed in the n-well region where the silicon nitride film has been removed;

the silicon nitride film is removed, prescribing a region for the p-well layer;

a p-type impurity is ion injected into the semiconductor substrate; and

the semiconductor substrate is heat treated, diffusing and activating the impurity.

### BRIEF DESCRIPTION OF THE DRAWINGS

In the accompanying drawings:

FIG. 1 is a circuit diagram of the comparator of the semiconductor device in the first embodiment of the present invention, having an n-type transistor as a differential transistor, and a p-type transistor as a load transistor;

FIG. 2 is a circuit diagram of the comparator of the semiconductor device in the sixth embodiment of the present invention, having a p-type transistor as a load transistor, and an n-type transistor as a differential transistor;

FIGS. 3A to 3G are process diagrams showing the method of manufacturing the MOS transistor of the comparator circuit of the semiconductor device in the first embodiment of the present invention;

FIG. 4 is a process diagram showing the finished product state of the MOS transistor of the comparator circuit of the semiconductor device in the first embodiment of the present invention;

FIG. 5 is a schematic cross sectional diagram of the MOS transistor of the comparator circuit of the semiconductor device in the first embodiment of the present invention;

FIG. 6 is a diagram showing the relationship between the VTP when there are two or more types of channel impurities and the boron channel dose;

FIG. 7 is a diagram showing the relationship between the VTN when there are two or more types of channel impurities and the boron channel dose;

FIG. 8 is a diagram showing the relationship between the channel dose and the mobility;

FIGS. 9A and 9B are process diagrams showing the method of manufacturing the semiconductor device according to the second embodiment of the present invention;

FIG. 10 is a diagram showing the relationship between the VTP for each N-well concentration and the BF₂ channel dose;

FIG. 11 is a diagram showing the relationship between the VTN for each P-well concentration and the BF₂ channel dose;

FIG. 12 is a diagram showing the relationship between the non-saturation VTP for each temperature and the mobility;

FIGS. 13A to 13C are process diagrams showing the method of manufacturing the semiconductor device according to the fourth embodiment of the present invention;

FIG. 14 is a schematic cross sectional diagram of a MOS transistor of the comparator circuit of the semiconductor device in the fifth embodiment of the present invention and a circuit other than the comparator circuit;

FIGS. 15A to 15C are process diagrams of the semiconductor device in the fifth embodiment of the present invention;

FIGS. 16A to 16C are process diagrams followed by those of FIGS. 15A to 15C;

FIGS. 17A to 17D are process diagrams followed by those of FIGS. 15A to 16C; and

FIG. 18 is a process diagram showing the finished product state of the circuit of the semiconductor device in the fifth embodiment of the present invention.

### DETAILED DESCRIPTION OF THE PREFERRED EMBODIMENTS

In a semiconductor device of the present invention, a high precision comparator occupying a small surface area and having a small offset voltage can be realized by using a MOS transistor.

The preferred embodiments of the present invention are explained below while referring to the figures.

A semiconductor device of a first embodiment of the present invention is shown. A comparator shown in the circuit diagram of FIG. 1 is structured by two p-type transistors 102 and 103 as load transistors, and two n-type transistors 107 and 108 as differential transistors, and is made up of a power source terminal 101, an output terminal 104, a reference voltage terminal 105, an input terminal 106, and a ground terminal 109. A certain fixed electric potential is applied to the reference voltage terminal 105. If the electric potential applied to the input terminal 106 at this point is smaller than the electric potential applied to the reference voltage terminal 105, then an electric potential applied to the power source terminal 101 will be output from the output terminal 104. On the other hand, if the electric potential applied to the input terminal 106 is larger than the electric potential applied to the reference terminal 105, then the electric potential applied to the ground terminal 109 is output from the output terminal 104. This change of output is called an inversion. For cases in which the size of the p-type transistors 102 and 103, used as load transistors, is equal, and in which the size of the n-type transistors 107 and 108, used as differential transistors, is equal, if the electric potential applied to the reference voltage terminal 105 is equal to the electric potential applied to the input terminal 106, then the output inverts. However, actually, inversion also occurs due to other causes such as manufacturing precision when the electric potential applied to the reference voltage terminal 105 and the electric potential applied to the input terminal 106 are not equal. The difference between the electric potential applied to the reference voltage terminal 105 and the electric potential applied to the input terminal 106 at this time is called an offset voltage. The offset voltage is found by the following equation:

V_{off}=ΔVₜₙ+√(αKₚ/βKₙ)×|ΔVₜₚ|+(√(α/β)−1)×(V_{ref}−V_{b}−Vₜₙ) (1)

where V_{off} is the offset voltage; ΔVₜₙ is the difference in threshold voltage (hereafter referred to as Vₜₕ) between the n-type transistors 107 and 108, which are the differential transistors; ΔVₜₚ is the difference in Vₜₕ between the p-type transistors 102 and 103, which are the load transistors; Kₙ is the mutual conductance of the n-type transistors 107 and 108, the differential transistors; Kₚ is the mutual conductance of the p-type transistors 102 and 103, the load transistors; α is the mutual conductance ratio of the load transistors, the p-type transistors 102 and 103; β is the mutual conductance ratio of the differential transistors, the n-type transistors 107 and 108; V_{ref} is the electric potential (hereafter referred to as V_{ref}) applied to the reference voltage terminal 105; Vₐ is the electric potential applied to the power source voltage terminal 101; V_{b} is the electric potential applied to the ground terminal 109; Vₜₙ is the Vₜₕ of the differential transistors, the n-type transistors 107 and 108; and Vₜₚ is the Vₜₕ of the load transistors, the p-type transistors 102 and 103.

Eq. (1) is found in the following manner. The channel width, the channel length, and the Vₜₕ of the load transistors, the p-type transistors 102 and 103, are mutually the same, and the channel width, the length, and the Vₜₕ of the differential transistors, the n-type transistors 107 and 108, are also mutually the same. If the current through the p-type transistor 102, the load transistor, and through the n-type transistor 107, the differential transistor, is taken as I₁, and the current through the p-type transistor 103, load transistor, and through the n-type transistor 108, the differential transistor, is taken as I₂. then the following equations are expressed:

I₁=Kₚ(Vₐ−V_{ref}−|Vₜₚ|)²=Kₙ(V_{ref}−V_{b}−Vₜₙ)² (2)

I₂=αKₚ{Vₐ−V_{dd}−|Vₜₚ−ΔVₜₚ|}²=βKₙ{Vᵢₙ−V_{b}−(Vₜₙ−)Vₜₙ)}² (3)

Vᵢₙ=V_{ref}−V_{off} (4)

where Vᵢₙ is the electric potential applied to the input terminal 106 (hereafter referred to as Vᵢₙ).

Fundamentally, if the channel width, the channel length, and the Vₜₕ of the load transistors, the p-type transistors 102 and 103, are mutually the same, and if the channel width, the length, and the Vₜₕ of the differential transistors, the n-type transistors 107 and 108, are also mutually the same, then inversion happens at Vᵢₙ=V_{ref}. However, if an offset voltage develops, then inversion occurs when eq. (4) is satisfied. At inversion I₁=I₂, and therefore eq. (2) becomes equal to eq. (3). If an offset voltage is assumed to develop, then eq. (4) is substituted. Eq. (1) is obtained by solving the above equations. From eq. (1) it is understood that in order to reduce the offset voltage, the mutual conductance of the load transistors may be made smaller, and the mutual conductance of the differential transistors may be made larger.

The p-type transistor mobility, in which holes are used as the operating carrier, is between one-half and on-third that of the n-type transistors, which have electrons as the carrier. The mutual conductance is proportional to mobilities, and therefore by using p-type transistors in the load side and n-type transistors in the differential side, the offset voltage can be made smaller as compared with the comparator structured by n-type transistors in the load side and p-type transistors in the differential side.

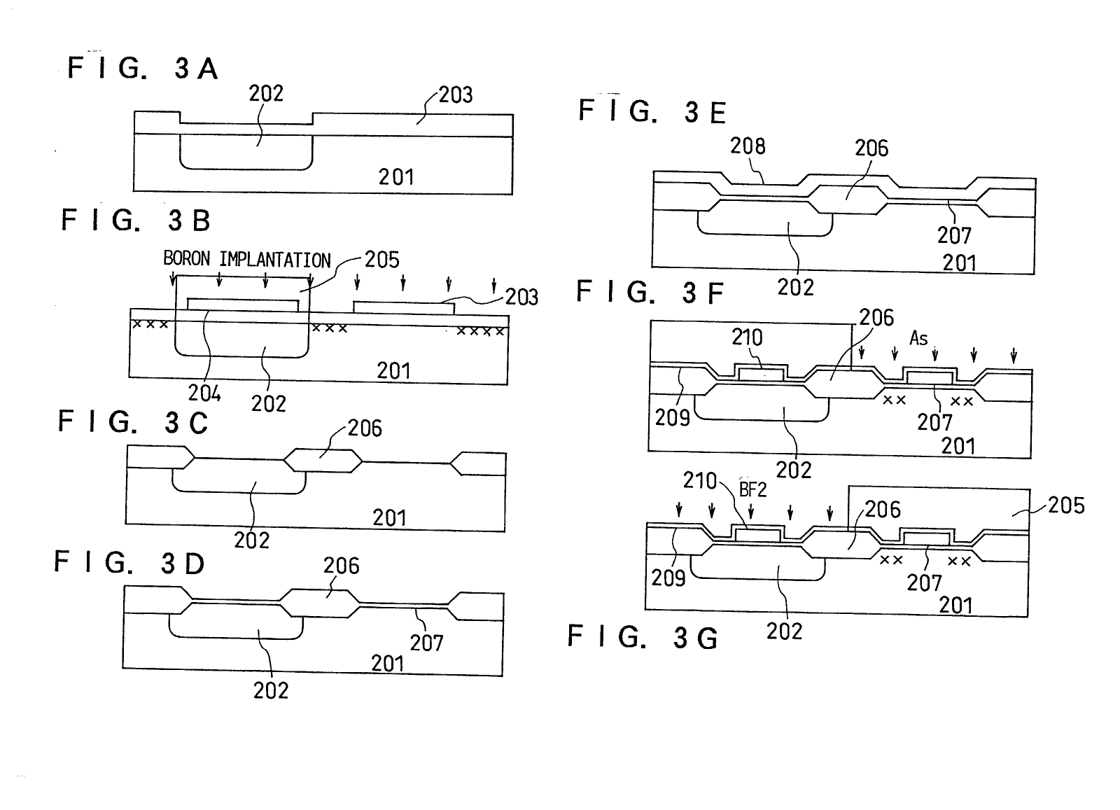

FIGS. 3A to 3G are cross sectional diagrams showing the steps of the method of manufacturing the semiconductor device of the present invention.

First, in a step FIG. 3A, an n-well layer 202 is formed in the surface of a p-type silicon semiconductor substrate 201. After forming a silicon oxide film 203 which is patterned into a predetermined shape as a mask on the substrate surface, an n-type impurity, phosphorous, for example, is ion injected at an acceleration energy of 100 to 180 Kev and with a dosage from 1×10¹² to 9×10¹² atoms/cm. Heat treatment is then performed at 1150/C. for 6 hours, performing diffusion and activation of the ion injected phosphorous impurity, and forming the n-well layer 202 as shown in the figures. P-channel MOS transistors which become the load transistors are formed in the n-well layer 202, and n-channel MOS transistors which become the differential transistors are formed in the neighboring section. Note that it is not always necessary to use the p-type silicon semiconductor substrate, and that an n-type silicon semiconductor substrate may be used to form a p-well region, p-type transistors which become load transistors in the n-type silicon semiconductor substrate, and n-type transistors which become differential transistors in the p-well region.

Field doping is performed in a step FIG. 3B. To do so, a silicon nitride film 204 is first patterned so as to cover an active region in which a transistor element is formed. On the top of the n-well in particular, a photoresist 205 is formed so as to overlap the silicon nitride film 204. The impurity boron is ion injected in this state at an acceleration energy of 30 Kev and a dose of between 1×10³³ and 9×10¹³ atoms/cm², performing field doping. As shown in the figures, a field doped region is formed in the area including the element region.

A so-called LOCOS process is then performed in a step FIG. 3C, forming a field oxide film 206 so as to surround the element region. Sacrificial oxidation and its removal process are then performed, and any foreign substances which remain on the surface of the substrate is removed for cleaning.

A thermal oxidation process is then performed on the substrate surface in a step FIG. 3D in an H₂O environment, forming an oxide film 207. The thermal oxide process in the present invention is performed in an O₂ environment at a temperature of 950° C., depositing an oxide film on the order of 300 Å. Normally it is necessary to set the film thickness of a gate insulating film formed by thermal oxidation to a film thickness on the order of 3 MV/cm in order to guarantee the reliability of the semiconductor device. For example, for a MOS transistor with a 30 V power supply voltage, an oxidation film thickness of 1000 Å or greater is necessary.

A polysilicon 208 is next deposited on the gate oxide film 207 by CVD, as shown in FIG. 3E. A 4000 Å polysilicon is formed in the present invention. The polysilicon 208 is changed to n-type in order to form a gate electrode 210 for a MOS transistor. The impurity element phosphorous is injected at a high concentration into the polysilicon 208 by ion injection or by using an impurity diffusion furnace. The injection concentration, in ions injected perpolysilicon film thickness, is 2×10¹⁹ atoms/cm³or greater. Note that is not always necessary to make the gate electrode for the MOS transistor into n-type, and that the impurity element boron may be injected at a high concentration by ion injection or by using an impurity diffusion furnace, making the gate electrode p-type.

After next removing the photoresist 205 formed by the previous step, a source/drain region of the n-channel MOS transistor is formed in a step FIG. 3F. The photoresist 205 remains as a mask on the n-well layer 202 in which the p-channel MOS transistor is formed at this time. The n-type impurity arsenic is ion injected at a dosage of between 3×10¹⁵ and 5×10⁹ atoms/cm² in a self-aligning manner by using the gate electrode 210 as a mask in this state. A thermal diffusion process is then performed at a temperature from 900 to 1050° C. in order to activate and diffuse the ion injected impurity. The thermal diffusion process is performed for approximately 30 minutes at 950° C. in the present invention.

A source/drain region of the p-channel MOS transistor are formed in a step FIG. 3G. The photoresist 205 masks the area of the previously formed n-channel MOS transistor at this time. The gate electrode 208 is used as a mask and the p-type impurity BF₂ is ion injected at a dosage of 3×10¹⁵ and 5×10¹⁶ atoms/cm² in a self aligning manner.

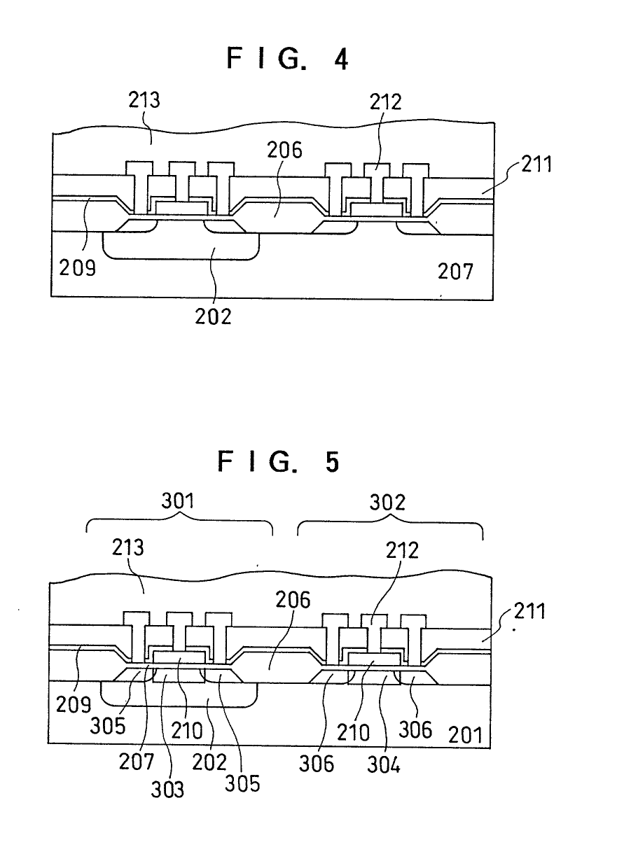

Processes such as metal wiring processing are explained next with reference to FIG. 4. Note that FIG. 4 shows the completed state of a CMOS transistor. As shown in the figure, after forming the source/drain region in the p-channel MOS transistor, the photoresist 205 is removed and a BPSG interlayer film 211 is deposited on the front face. The interlayer film is formed by CVD, for example, and is leveled by heat treatment at 920/C. for approximately 75 minutes. The interlayer film is then selectively etched, and contact holes are formed in communication to the source/drain region and the gate electrode. A contact reflow process is performed next. Heat treatment is performed at 880/C. for approximately 30 minutes in the present invention. A metallic material is then deposited over the entire surface by vacuum evaporation or sputtering, after which photo lithography and etching are performed, forming a patterned metal wiring 212. Finally, the entire substrate is covered by a surface protecting film 213.

A second embodiment of the semiconductor device of the present invention is explained. FIG. 5 is a schematic cross sectional diagram of a p-type transistor, a load transistor, and an n-type transistor, a differential transistor, of the semiconductor device of the present invention.

The n-type transistor is made up of a gate oxide film 311 and a polycrystalline silicon gate electrode 305 formed on a p-type silicon semiconductor substrate 301, high concentration “n+”-type diffusion layers 304 called source and drain formed on the surface of the silicon substrate at both ends of the gate electrode, and a channel region 307 formed between the source and the drain. Further, the p-type transistor is made up of the gate oxide film 311 and the polycrystalline silicon gate electrode 305 formed on the silicon substrate, high concentration “p+”-type diffusion layers 303 called source and drain formed on the surface of an “n−”-type well layer 302 at both ends of the gate electrode and a channel region 306 formed between the source and the drain. A field oxide film 308 is formed between both elements for the purpose of separation.

A p-type impurity such as boron or BF₂, or an n-type impurity such as As or phosphorous, is introduced into the channel region of the MOS transistor. When the polycrystalline silicon gate electrode is n-type, a p-type impurity such as boron or BF₂ is introduced into the channel region of an enhanced type and a depressed type p-channel MOS transistor. For the channel region of an n-channel MOS transistor, a p-type impurity such as boron or BF₂ is introduced in the case of an enhanced type, and an n-type impurity such as As or phosphorous is introduced in the case of a depressed type. When the polycrystalline silicon gate electrode is p-type, an n-type impurity such as boron or BF₂ is introduced into the channel region of a p-channel MOS transistor in the case of an enhanced type, and a p-type impurity such as As or phosphorous is introduced in the case of a depressed type. An n-type impurity such as As or phosphorous is introduced into the channel region of an enhanced type and of a depressed type n-channel MOS transistor. The impurity concentration on the load side is made higher than the concentration on the differential side of the channel region at this time, lowering the mobility.

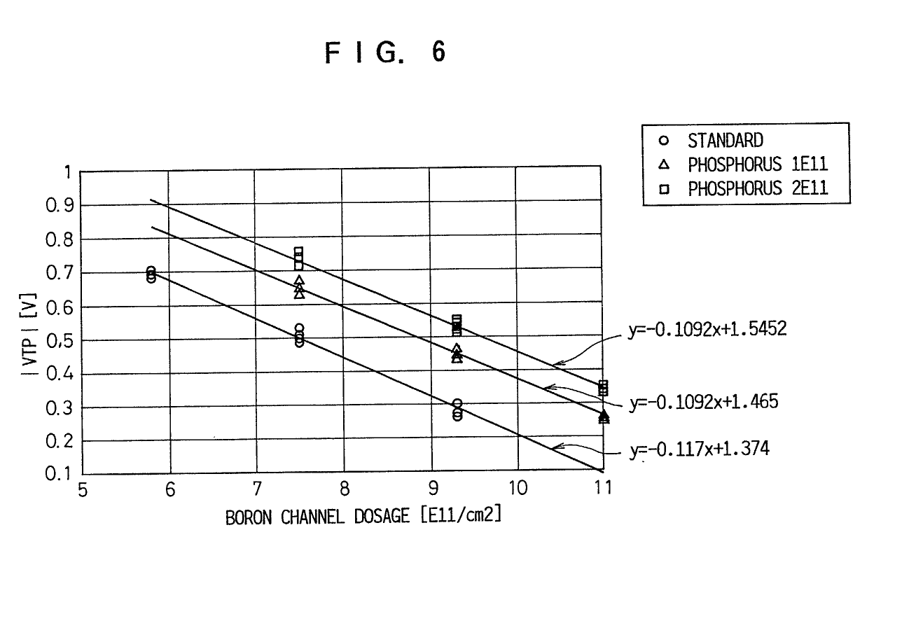

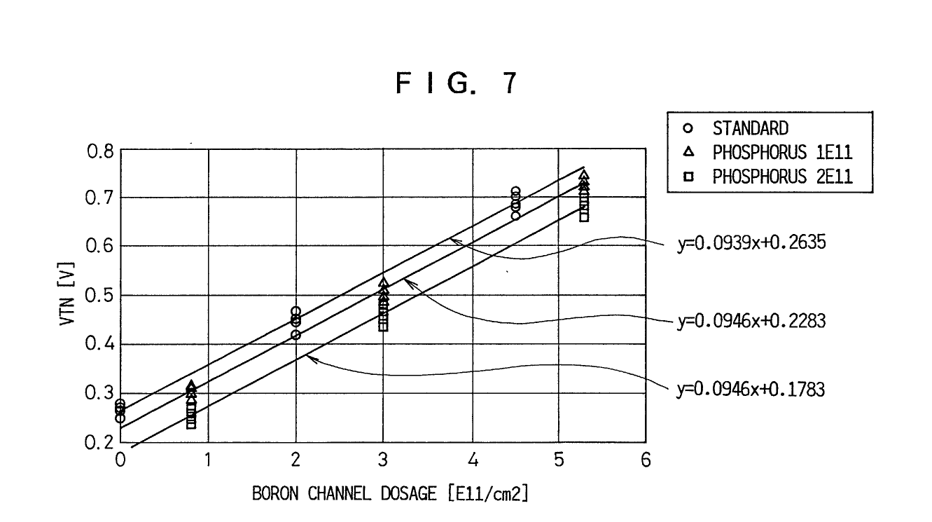

In addition, the mobility can also be lowered by introducing two or more types of impurities into the channel region of the load side MOS transistor. In this case a p-type impurity and an n-type impurity must always be mixed. For example, after introducing a somewhat n-type impurity, a p-type impurity is introduced. P-type and n-type impurities offset electrically, and therefore even if a large amount of impurity (p-type) is introduced, the same properties (threshold voltage) can be obtained. A graph of VTP vs. boron channel dosage is shown in FIG. 6. For example, to make a VTP of 0.5 v, with a conventional (standard) channel impurity (boron) of 7.47×10¹¹ atoms/cm², 1×10¹¹ atoms/cm² of phosphorous are intermixed, and 8.84×10¹atoms/cm² are introduced, and if 2×10¹¹ atoms/cm² of phosphorous are intermixed, 9.57×10¹¹ atoms/cm² are introduced. In other words, if a heteropolar impurity is intermixed, then a lot of the impurity can be introduced at the same VTP. FIG. 7 shows a graph of VTN vs. boron channel dosage. Similarly, if an n-type impurity such as phosphorous is intermixed, then a large amount of a p-type impurity can be introduced at the same VTN. For example, to make a VTN of 0.5 v, with a conventional (standard) channel impurity (boron) of 2.52×10¹¹ atoms/cm², 1×10¹¹ atoms/cm² of phosphorous are intermixed, and 2.87×10¹¹ atoms/cm² are introduced, and if 2×10¹¹ atoms/cm² of phosphorous are intermixed, 3.40×10¹¹ atoms/cm² are introduced.

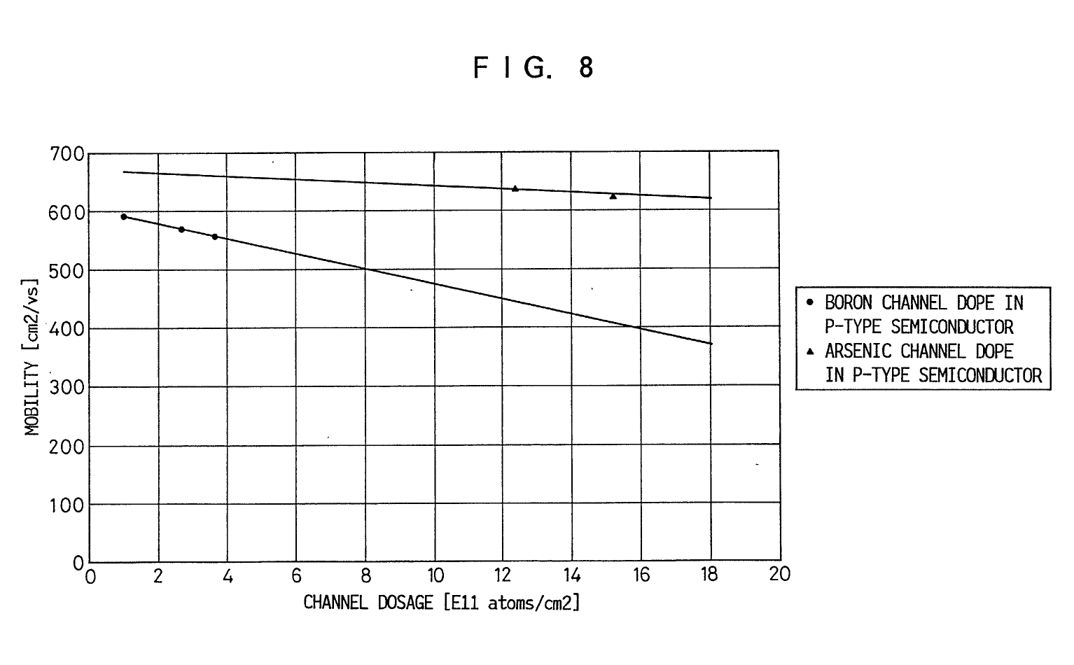

The change in mobility when the impurity is introduced into the channel region of the MOS transistor is explained next. The relationship between the dosage and the mobility when boron, an impurity with the same conductivity type as the substrate, and arsenic, an impurity with the inverse type of conductivity, are introduced in the channel region of the p-type semiconductor substrate is shown in FIG. 8. As the channel dosage increases, the mobility becomes smaller. From this, it is understood that by introducing the impurity into the channel region, the mobility is easily changed. Thus by making the channel impurity concentration on the load side higher than the channel impurity concentration on the differential side, the mutual conductance of the load side MOS transistor becomes less than the mutual conductance of the differential side MOS transistor, and the offset voltage can be made smaller.

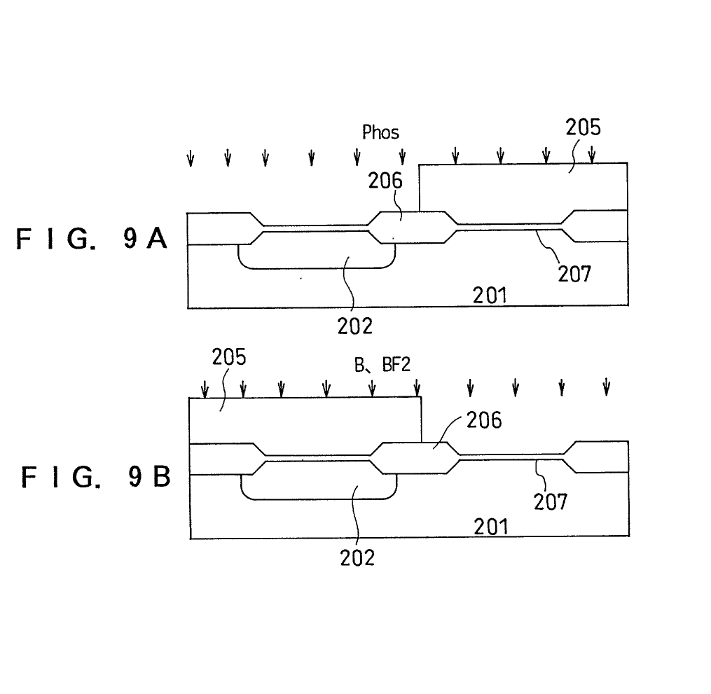

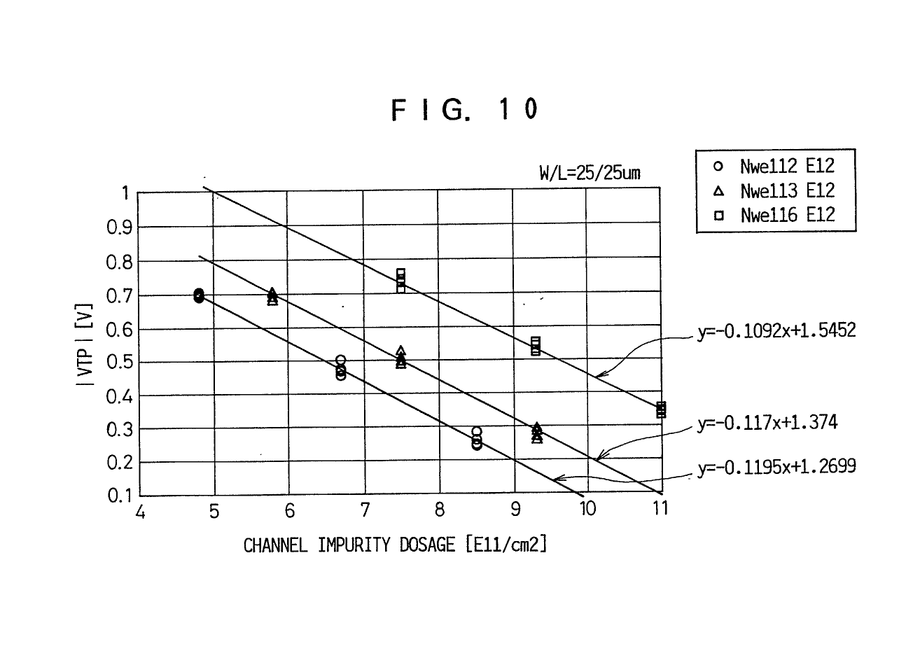

FIGS. 9A and 9B are process diagrams showing the method of manufacturing the semiconductor device of the second embodiment of the present invention. The formation process of a channel doped layer of the CMOS transistor structuring a comparator is explained while referring to FIGS. 9A and 9B. The processes leading up to the processes of a step I are the same as those of FIG. 3D.

A channel doping is performed in step I, as shown in FIG. 9A, in order to regulate the mobility (mutual conductance) of the p-channel MOS transistor, which becomes the load transistor. The photoresist 205 is patterned everywhere except on the n-well layer 202 which forms the p-channel MOS transistor. Then an impurity is injected. For example, an n-type impurity such as arsenic or phosphorous is injected.

Note that a p-type impurity may also be injected, and that both an n-type impurity and a p-type impurity may be injected. The photoresist 205 becomes a mask in the neighboring region in which the n-channel MOS transistor is expected to be formed, and the impurity is not injected. The photoresist formed by the previous step is then removed. Further processes are the same as those of FIGS. 3E to 3G, and FIG. 4. Note that when the n-channel MOS transistor becomes the load transistor, the photoresist is patterned on the n-well layer in which the p-channel MOS transistor is formed. An impurity is then injected. For example, a p-type impurity such as boron or BF₂ is injected. Note that an n-type impurity may be injected, and that both an n-type impurity and a p-type impurity may be injected. The photoresist becomes a mask in the neighboring region in which the p-channel MOS transistor is expected to be formed, and the impurity is not injected.

Furthermore, regulation of the mobility (mutual conductance) of both the load transistor and the differential transistor may also be performed. A formation process of the channel doped layer of the n-channel MOS transistor which becomes the differential transistor is explained. Processes up to a step II, as shown in FIG. 9B, are the same as in the step I of FIG. 9A. In step II, channel doping is performed in order to regulate the mobility (mutual conductance) of the n-channel MOS transistor which becomes the differential transistor. After removing the photoresist 205 formed in the previous step, the photoresist 205 masks regions outside the region in which the n-channel MOS transistor is formed, and an impurity is injected. For example, a p-type impurity such as boron or BF₂ is injected. The photoresist 205 formed in the previous step is next removed. Further processing is the same as the processes of FIGS. 3E to 3G, and FIG. 4. Note that the impurity is injected so that the mobility (mutual conductance) of the load transistor is always larger than the mobility (mutual conductance) of the differential transistor. Further, it is not always necessary to use the n-channel MOS transistor as the differential transistor.

Further, for the case when arsenic is the impurity injected in order to regulate the mobility (mutual conductance) of the MOS transistor, it is better to perform injection of the impurity before forming the gate oxide film. That formation process is explained. The processes up to the steps of FIG. 3C are the same, and then an oxide film is formed on the order of 200 to 400 Å, and the photoresist is patterned on the regions outside the well layer in which the MOS transistor injected with arsenic is formed. The n-type impurity arsenic is then injected. The photoresist becomes a mask in the neighboring regions in which the MOS transistor without impurity injection is expected to be formed, and the impurity is not injected. The photoresist formed by the previous step is then removed. Further processes are the same as the processes of FIGS. 3D to 3G and FIG. 4. Note that if boron, BF₂, or phosphorous is injected, further processes are performed in the order of FIG. 3D→FIG. 9A→FIG. 9B→FIGS. 3E to 3G→FIG. 4.

Furthermore, it is not always necessary to perform the channel doping in order to regulate the mobility of the MOS transistor. It may also be performed in order to regulate the threshold voltage.

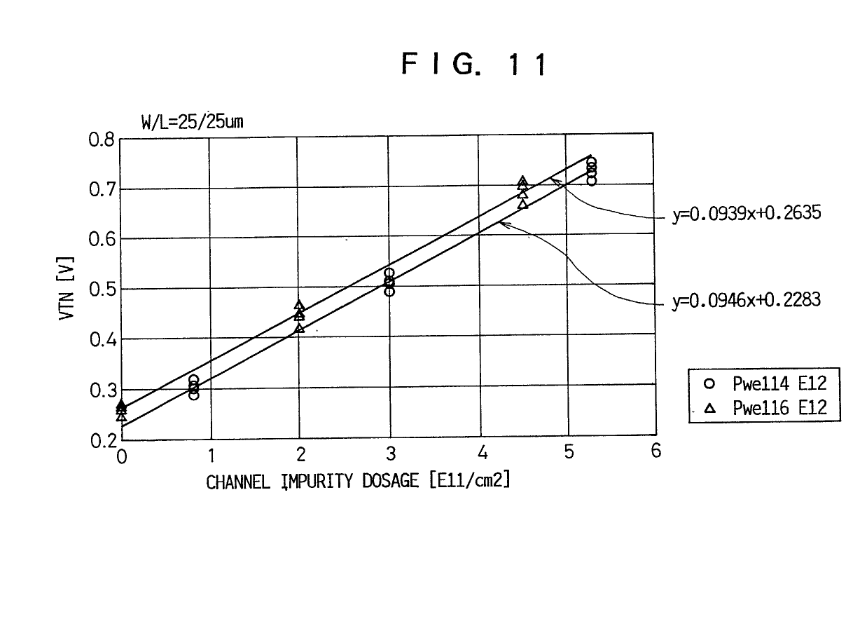

A third embodiment of the semiconductor device of the present invention is explained in detail. The threshold voltage of a p-type transistor which becomes a load transistor is made higher than the threshold voltage of an n-type transistor which becomes a differential transistor. A graph of p-type transistor vs. channel impurity amount is shown in FIG. 10, and a graph of n-type transistor vs. channel impurity amount is shown in FIG. 11. For a case in which the threshold voltage of the p-type transistor is, for example, 0.6 v, it is necessary for the channel impurity to be 6.62×10¹¹ atoms/cm², and when the threshold voltage of the n-type transistor is, for example, 0.5 v, then it is necessary for the channel impurity to be 2.87×10¹¹atoms/cm². The one with a higher threshold voltage has a larger channel impurity amount. In other words, if the threshold voltage of the load side MOS transistor is higher than the threshold voltage of the differential side MOS transistor, the offset voltage can be made smaller. In addition, the higher the threshold voltage of the p-type transistor the better. A graph of the p-type transistor vs. mobility is shown in FIG. 12. It can be understood that the higher the threshold voltage, the smaller the mobility becomes.

In order to make the impurity concentration of the channel region of the p-type transistor, the load transistor, even higher than the impurity concentration of the channel region of the n-type transistor, the differential transistor, it is effective to make the p-type transistor, the load transistor, in the concentrated n-type well region. A graph of VTP vs. channel impurity amount is shown in FIG. 10 for several n-well concentrations. For example, to make a VTP of 0.5 v, it is necessary that the channel impurity (boron) be 6.44×10¹¹ atoms/cm² at an n-well of 2×10¹² atoms/cm², 7.47×10¹¹ atoms/cm² at 3×10¹² atoms/cm², and 9.57×10¹¹ atoms/cm² at 6×10¹². The amount of the channel impurity becomes greater as the n-well concentration increases.

If the mobility of the p-type transistor, the load transistor, is smaller than the mobility of the n-type transistor, the differential transistor, then it is possible to form well regions in both the p-type transistor, the load transistor, and in the n-type transistor, the differential transistor. The impurity concentration of the channel region of the n-type transistor can be largely different from the impurity concentration of the channel region of the p-type transistor at this point. A graph of VTN vs. channel impurity amount is shown in FIG. 8 for each p-well concentration. For example, to make a VTN of 0.45 v, it is necessary that the channel impurity amount be 2.34×10¹¹ atoms/cm² at a p-well of 4×10¹² atoms/cm², and 1.99×10¹¹ atoms/cm² at 6×10¹² atoms/cm². Thus the higher the p-well concentration, the lower the channel impurity amount can be made, making the difference larger.

Further, it is not always necessary to make the MOS transistor of the load side in the well region. Using an n-type substrate, a p-type well is formed, and the p-type transistor which becomes the load transistor may be formed within the n-type silicon semiconductor substrate, while the n-type transistor which becomes the differential transistor may be made inside the p-type well. In this case the impurity concentration of the channel region in the p-type transistor which becomes the load transistor is always made higher than that of the channel region of the n-type transistor which becomes the differential transistor.

A fourth embodiment of the semiconductor device of the present invention is explained in detail. The thickness of a gate oxide film of a load side MOS transistor is made thicker than that of a differential side MOS transistor, making the offset voltage smaller. The mutual conductance is inversely proportional to the gate oxide film thickness. Making the gate oxide film thicker gives a smaller mutual conductance. An oxide film with a thickness of 150 Å, for example, is formed on the entire surface of a semiconductor substrate, after which the oxide film in only a region where the MOS transistor of the differential side will be formed is selectively etched, and an oxide film with a thickness of 200 Å, for example, is again formed, on the entire oxide surface of the substrate. Thus the thickness of the gate oxide film of the differential side MOS transistor becomes the 200 Å film thickness of the final oxidation, and a gate oxide film with a thickness of 150+200 Å, on the order of 300 Å, is formed for the load side MOS transistor, and the mutual conductance of the load side MOS transistor can be made smaller than that of the differential side transistor.

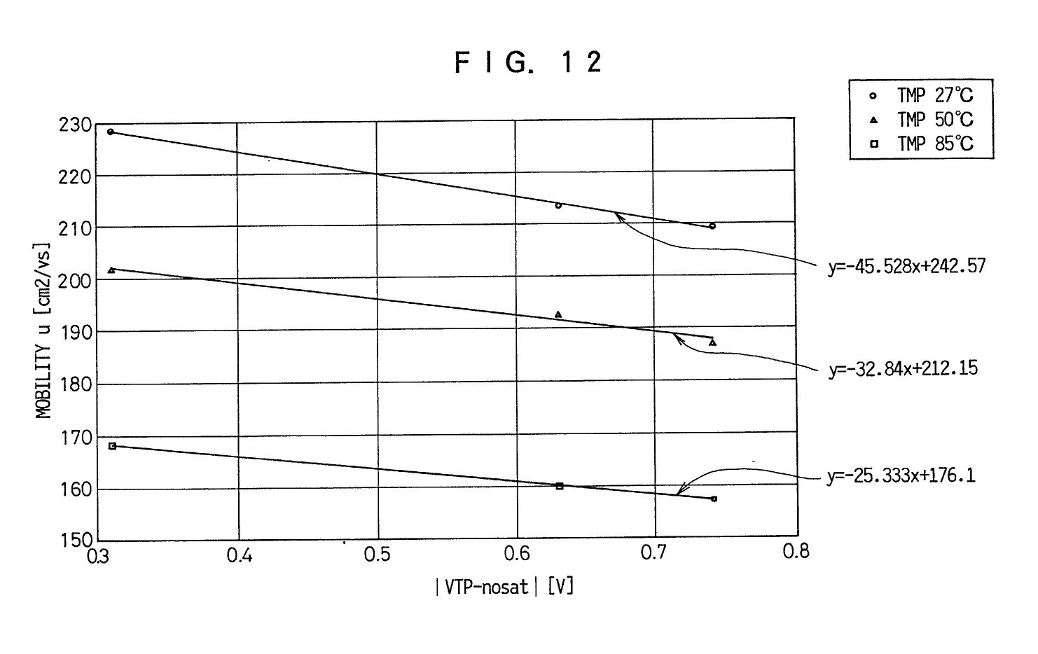

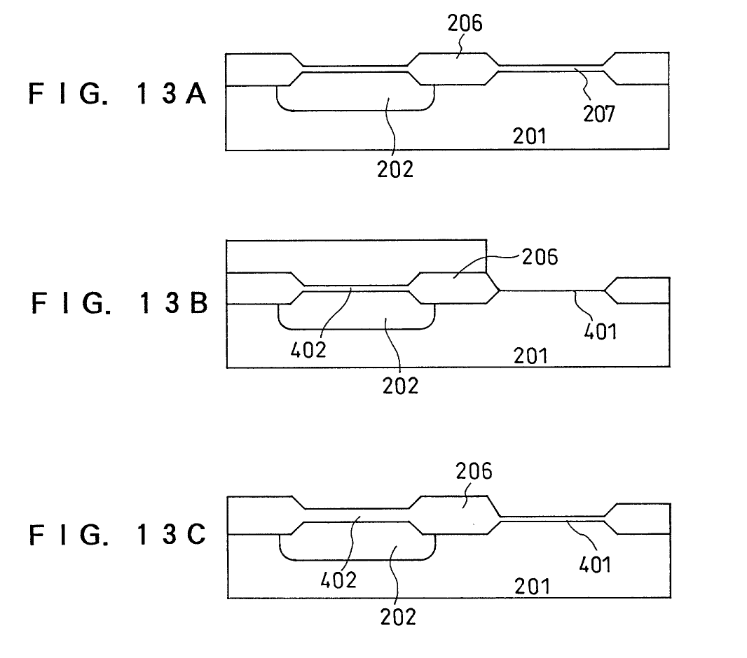

FIGS. 13A to 13C are process diagrams showing the method of manufacturing the semiconductor device according to the fourth embodiment of the present invention. The formation process of the oxide film of a CMOS transistor structuring a comparator is explained while referring to FIGS. 13A to 13C. The processes up to step FIG. 13A are the same as those of FIG. 3C. The oxide film 207 is deposited by a thermal oxidation process of the substrate surface in an H₂O environment in the step FIG. 13A.

Afterward, in a step B, the photoresist 205 deposited by CVD on the n-well layer 202, in which a p-channel MOS transistor which becomes the load side transistor is formed, is patterned, and an oxide film 401 on an n-channel MOS transistor which becomes the differential transistor is etched.

After next removing the photoresist 205 formed by the previous step, an oxide film is formed by heat treatment in a step FIG. 13B. The oxide film is formed in an O₂/H₂ environment at 800° C. with a thickness of 150 Å in the present invention, etching is performed, and then a 200 Å oxide film is formed in an O₂ environment at 950° C. As a result, a gate oxide film 402 of the p-channel MOS transistor is 300 Å, and the gate oxide film 401 of the n-channel MOS transistor is 200, Å, as shown in FIG. 13C.

Note that it is not always necessary to make the gate oxide film thick on the n-well in which the p-channel MOS transistor is formed. When the n-channel MOS transistor is used as the load transistor, a photoresist is patterned on the substrate or on the well layer in which the n-channel MOS transistor is formed, and the oxide film on the p-channel MOS transistor which becomes the differential transistor is etched.

A fifth embodiment of the semiconductor device of the present invention is explained in detail. FIG. 14 is a schematic cross sectional diagram of a MOS transistor which structures the comparator circuit 501 inside a power supply IC, LCD controller IC, etc., and of a MOS transistor of the circuit 502 which is a circuit other than a comparator circuit.

The comparator circuit 501 structured by an n-type MOS transistor 504 of the differential side and by a p-type MOS transistor 503 of the load side. The n-type MOS transistor 504 of the differential side includes side spacers 512 formed at both sides of the gate electrode, low concentration diffusion layers (n-LDD) 509 formed in a silicon substrate below the side spacers, and high concentration diffusion layers (N+-diffusion layers) 306, called source and drain, formed on the sides of the low concentration diffusion layers 509. A so-called n-type LDD transistor can be obtained. An n-type MOS transistor 506 of the circuit other than the comparator circuit is the same LDD transistor.

The side spacers 512 are similarly formed at both sides of the gate electrode in a p-type MOS transistor 503 of the load side, but there is no low concentration diffusion layer (LDD) in the silicon substrate below the side spacers. High concentration diffusion layers (p+diffusionlayers) 305, called source and drain, are formed so as not to overlap with the gate electrode, Thus when the p-type MOS transistor is operated, the LDD portion works as a resistor, and the mutual conductance can be made smaller without increasing the transistor size. In contrast, for a p-type MOS transistor 505 of the circuit other than the comparator circuit, an LDD 508 is formed and the operation speed (mutual conductance) does not become smaller. Thus the mutual conductance only becomes smaller for the load side MOS type transistor of the comparator circuit in the IC, and the offset voltage can be reduced without lowering the characteristics of other circuits.

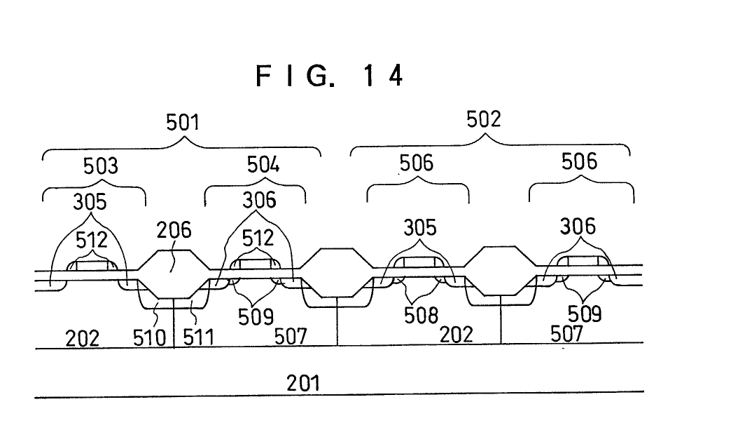

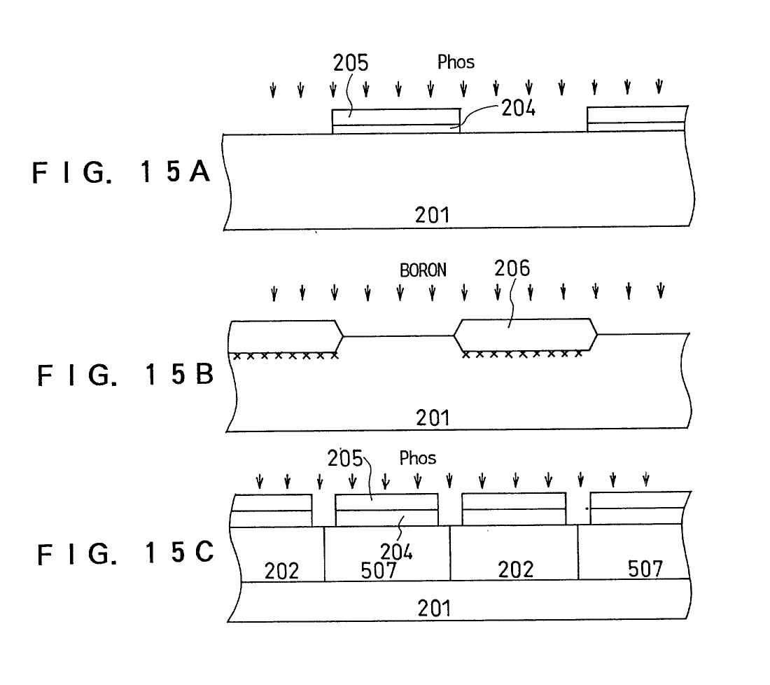

FIGS. 15A to 17D are cross sectional views showing a method of manufacturing a semiconductor device like that of FIG. 14.

First, the n-well layer 202 is formed in the surface of the p-type silicon semiconductor substrate 201 in a step A. After forming the silicon nitride film 204 patterned into a predetermined shape is formed as a mask on the substrate surface, an n-type impurity, phosphorous, for example, is ion injected at an acceleration energy of 100 to 180 Kev and a dosage from 1×10¹² to 9×10¹² atoms/cm², as shown in FIG. 15A.

A so-called Locos process is then performed in a step B, and the silicon nitride film 204 formed in the previous step is removed. A p-type impurity, boron for example, is ion injected at an acceleration energy of 30 Kev and a dose of between 1×10¹³ and 9×10¹³ atoms/cm², heat treatment is performed at 1150° C. for 6 hours, performing diffusion and activation of the injected impurities phosphorous and boron, and forming the n-well layer 202 and a p-well layer 507 as shown in the figures. The p-channel MOS transistor which becomes the load transistor and the p-channel MOS transistor which structures the circuit other than the comparator circuit are formed in the n-well layer 202, and the n-channel MOS transistor which becomes the differential transistor and the n-channel MOS transistor which structures the circuit other than the comparator circuit are formed in the p-well layer 507, as shown in FIG. 15B.

Field doping is performed in a step C. To do so, the silicon nitride film 204 is first patterned so as to cover an active region in which a transistor element is formed. The photoresist 205 is also formed so as to overlap the silicon nitride film 204. The impurity phosphorous is ion injected in this state at an acceleration energy of 90 Kev and a dose of between 1×10¹² and 9×10¹² atoms/cm², performing field doping, as shown in FIG. 15C.

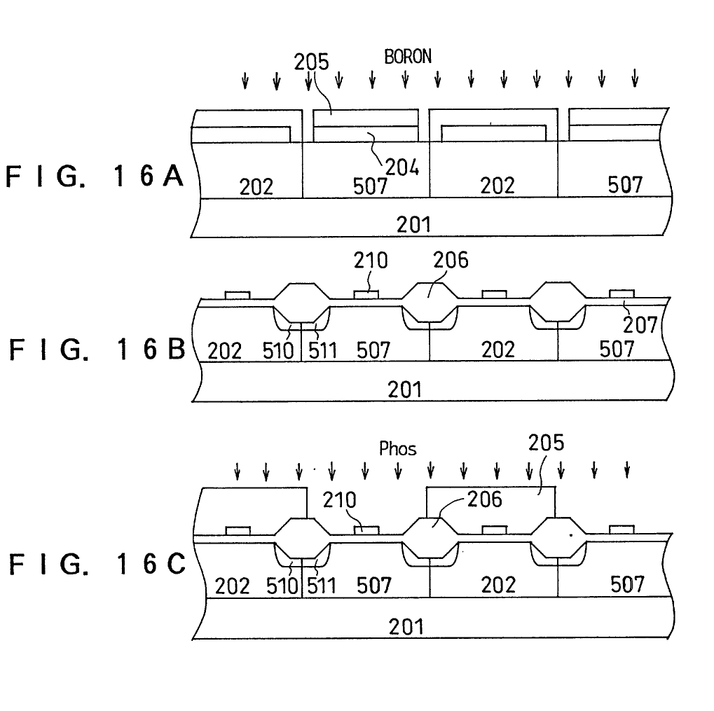

Next, the photoresist 205 is patterned on the n-well layer 202 in a step D. Boron is ion injected in this state at an acceleration energy of 30 Kev and a dose of between 1×10¹³ and 9×10¹³ atoms/cm², performing field doping. As shown in the figures, a field doped region is formed in the area including the-element region, as shown in FIG. 16A.

After then removing the photoresist formed by the previous step, the so-called LOCOS process is performed in a step E, forming the field oxide film 206 so as to surround the element region. Next, the silicon nitride film 204 is removed, sacrificial oxidation and its removal process are performed, and cleaning is done to remove any foreign substances which remain on the surface of the substrate A thermal oxidation process is then performed on the substrate surface in an O₂ environment, forming the oxide film 207. The thermal oxide process in the present invention is performed in an O₂ environment at a temperature of 950° C., depositing an oxide film on the order of 300 Å. Normally it is necessary to set the film thickness of a gate insulating film formed by thermal oxidation to a film thickness on the order of 3 MV/cm in order to guarantee the reliability of the semiconductor device. For example, for a MOS transistor with a 30 V power supply voltage, an oxidation film thickness of 1000 Å or greater is necessary. The photoresist formed by the previous step is removed, and the polysilicon 208 is next deposited on the gate oxide film 207 by CvD. A 4000 Å polysilicon is formed in the product of the present invention. The polysilicon 208 is changed to n-type in order to form the gate electrode 210 for the MOS transistor. The impurity element phosphorous is injected at a high concentration into the polysilicon 208 by ion injection or by an impurity diffusion furnace. The injection concentration, in ions injected per polysilicon film thickness, is 2×10¹⁹ atoms/cm³ or greater, as shown in FIG. 16B.

After next removing the photoresist 205 formed by the previous step, the low concentration diffusion layers (n-LDD) 409 of the n-channel MOS transistor are formed. At this time, the photoresist 205 masks the n-well layer 202 in which the p-channel MOS transistor is formed. The n-type impurity phosphorous is ion injected at a dosage of between 1×10¹³ and 1×10¹⁴ atoms/cm² in a self-aligning manner by using the gate electrode 210 as a mask in this state. In the fifth embodiment the impurity phosphorous is ion injected at an acceleration energy of 50 KeV and a dosage of 5×10¹³ atoms/cm², as shown in FIG. 16C.

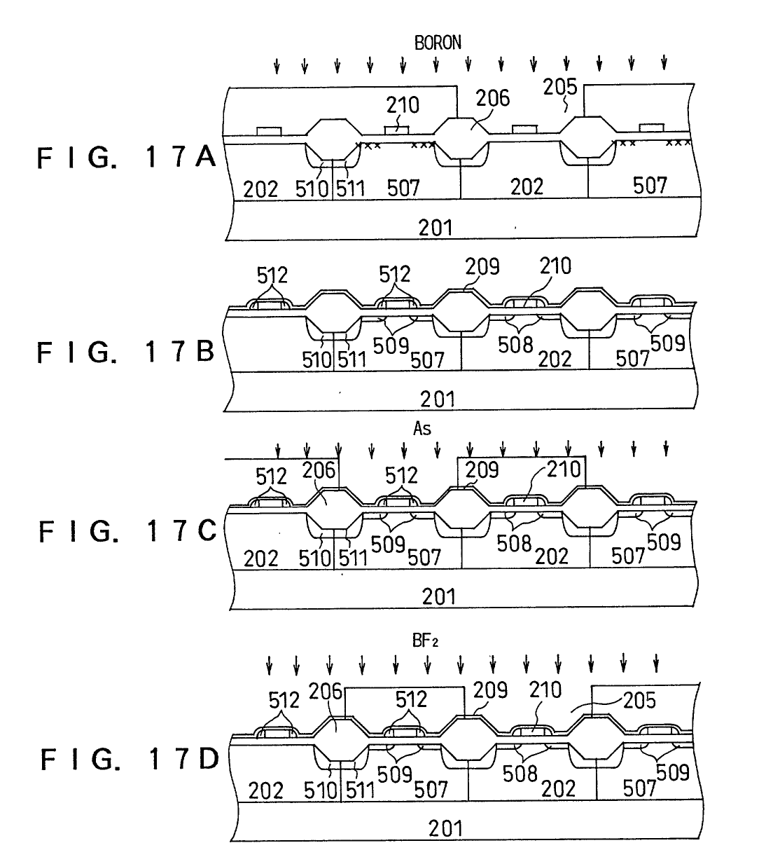

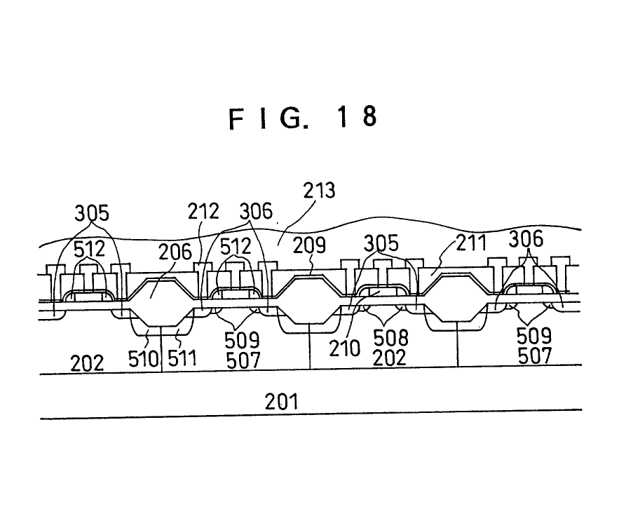

The photoresist 205 formed in the previous step is then removed in a step G, and a low concentration diffusion layer (p-LDD) of the p-channel MOS transistor structuring the circuit other than the comparator circuit is formed. The photoresist 205 masks at this time the p-well layer 507 in which the n-channel MOS transistor is formed and also masks the p-well MOS transistor structuring the comparator circuit. The p-type impurity BF₂ is ion injected in this state at a dosage of between 1×10¹⁴ and 1×10 15 atoms/cm² in a self-aligning manner using the gate electrode 210 as a mask. In the fifth embodiment the impurity BF₂ is ion injected at an acceleration energy of 70 KeV and a dosage of 5×10¹⁴ atoms/cm². A thermal diffusion process is performed next in order to activate and diffuse the ion injected impurities. In the present invention thermal diffusion is performed at 950° C. for approximately 30 minutes, as shown in FIG. 17A.

After removing the photoresist 205 formed in the previous step, the side spacers 412 are formed in a step H. First, the TEOS oxide film 207 is formed on the substrate surface. A 5000 Å oxide film is formed in the product of the present embodiment. The side spacers are next formed by dry etching, and an oxide film with a film thickness of between 100 and 300 Å is formed on the substrate surface, as shown in FIG. 17B.

The source/drain region of the n-channel MOS transistor is formed next in a step I. At this time, the photoresist 205 masks then-well layer 202 in which the p-channel MOS transistor is formed. The n-type impurity arsenic is ion injected in this state at a dosage of between 3×10¹⁵ and 5×10¹⁹ atoms/cm² in a self-aligning manner using the gate electrode 210 as a mask. A thermal diffusion process is then performed in order to activate and diffuse the ion injected impurity. The thermal diffusion process is performed for approximately 30 minutes at 950° C. in the present invention, as shown in FIG. 17C.

A source/drain region of the p-channel MOS transistor is formed in a step J. The photoresist 205 masks the area of the previously formed n-channel MOS transistor at this time. The p-type impurity BF₂ is ion injected in this state at a dosage of 3×10¹⁵ and 5×10¹⁶ atoms/cm² in a self aligning manner using the gate electrode 208 as a mask, as shown in FIG. 17D.

Processes such as metal wiring processing are explained next with reference to FIG. 18. Note that FIG. 18 shows the completed state of a CMOS transistor As shown in the figure, after forming the source/drain region in the p-channel MOS transistor, the photoresist 205 is removed and the BPSG interlayer film 211 is deposited on the front face. The interlayer film is formed by CVD, for example, and is leveled by heat treatment at 920° C. for approximately 75 minutes. The interlayer film is then selectively etched, and contact holes are formed in communication to the source/drain region and the gate electrode. A contact reflow process is performed next. Heat treatment is performed at 880° C. for approximately 30 minutes in the present invention. A metallic material is then deposited over the entire surface by vacuum evaporation or sputtering, after which photo lithography and etching are performed, forming a patterned metal wiring 212. Finally, the entire substrate is covered by a surface protecting film 213. Note that it is not always necessary to use a p-type silicon semiconductor substrate. An n-type silicon semiconductor substrate may be used, with a p-well region and an n-well region formed. The p-type transistor which becomes the load transistor and the p-type transistor which structures the circuit other than the comparator circuit may be formed in the n-type silicon semiconductor substrate, and the n-type transistor which becomes the differential transistor and the n-type transistor which structures the circuit other than the comparator circuit are may be formed in the p-well region.

A sixth embodiment of the semiconductor device of the present invention is explained in detail. Up to now the load side has been stated as a p-type transistor and the differential side has been stated as an n-type transistor, but an example of a comparator circuit in which a p-type transistor is taken as the differential transistor and in which an n-type transistor is taken as the load transistor is shown below.

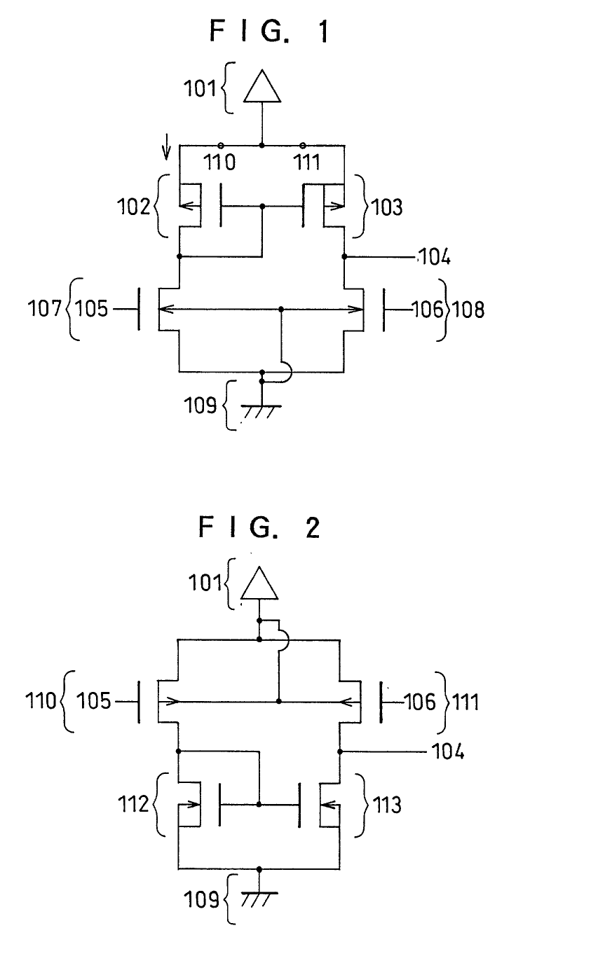

The comparator shown in FIG. 2 is structured with the two n-type transistors 203 and 204 as the load transistors, and the two p-type transistors 201 and 202 as the differential transistors. An explanation for other sections is omitted by attaching the same symbols as in FIG. 1. Similar to FIG. 1, the offset voltage for FIG. 2 can be found by the following equation;

V_{off}|ΔVₜₚ|+√(βKₙ/αKₚ)×ΔVₜₙ+(√(β/α)−1)×(Vₐ−V_{ref}−|Vₜₚ|) (5)

where Vₜₚ is the Vₜₕ of the p-type transistor 201, the load transistor; Vₜₙ is the Vₜₕ of the n-type transistor 203, the differential transistor; ΔVₜₚ is the difference in Vₜₕ between the p-type transistors 201 and 202, which are the differential transistors; ΔVₜₙ is the difference in Vₜₕ between the n-type transistors 203 and 204, which are the load transistors; Kₚ is the mutual conductance of the p-type transistor 201, the differential transistor; Kₙ is the mutual conductance of the n-type transistor 203, the load transistor; α is the mutual conductance ratio of the differential transistors, the p-type transistors 201 and 202; andβ is the mutual conductance ratio of the load transistors, the n-type transistors 203 and 204. From eq. (5) it is understood that in order to reduce the offset voltage, the mutual conductance of the load transistors may be made smaller, and the mutual conductance of the differential transistors may be made larger. Therefore, the above stated means of making the mutual conductance of the n-type transistors, the load transistors, smaller may be taken in order to make the offset voltage smaller for this type of circuit as well.

As stated above in accordance with the present invention, if the mutual conductance of the load side MOS transistor is made smaller than the mutual conductance of the differential side MOS transistor in a comparator which uses MOS transistors, then the offset voltage can be made smaller without increasing the transistor size. Thus it is possible to provide a comparator having a small offset voltage which is impossible with a conventional comparator, and occupying a small surface area. In addition to being able to lower costs, the comparator can be applied to an IC having a restricted chip size, and a great effect can be obtained in most ICs.

What is claimed is:

1. A semiconductor device comprising a comparator structured by MOS transistors, wherein the mutual conductance of the MOS transistors of the load side is smaller than the mutual conductance of the MOS transistors of the differential side.

2. The semiconductor device according to claim 1, wherein the mobility of the MOS transistors of the load side of the comparator is smaller than the mobility of the MOS transistors of the differential side.

3. The semiconductor device according to claim 1, wherein the impurity concentration in the channel region of the MOS transistors of the load side of the comparator is higher than the impurity concentration in the MOS transistors of the differential side.

4. The semiconductor device according to claim 1, wherein the threshold voltage of the MOS transistors of the load side of the comparator is higher than the threshold voltage of the MOS transistors of the differential side.

5. The semiconductor device according to claim 1, wherein the gate oxide film thickness of the MOS transistors of the load side of the comparator is thicker than the gate oxide film thickness of the MOS transistors of the differential side.

6. The semiconductor device according to claim 1, wherein the MOS transistors of the load side of the comparator are p-type transistors, and the MOS transistors of the differential side are n-type transistors.

7. The semiconductor device according to claim 1, wherein the MOS transistors of the load side of the comparator are n-type transistors, and the MOS transistors of the differential side are p-type transistors.

8. The semiconductor device according to claim 3, wherein the impurity introduced into the channel region of the MOS transistors is phosphorous.

9. The semiconductor device according to claim 3, wherein the impurity introduced into the channel region of the MOS transistors is arsenic.

10. The semiconductor device according to claim 3, wherein the impurity introduced into the channel region of the MOS transistors is boron.

11. The semiconductor device according to claim 3, wherein the impurity introduced into the channel region of the MOS transistors is BF₂.

12. The semiconductor device according to claim 3, wherein two or more impurities are introduced into the channel region of the MOS transistors.

13. The semiconductor device according to claim 1, wherein only the MOS transistors of the load side of the comparator include a gate electrode that does not overlap with a source diffusion and a drain diffusion formed in a substrate.

14. A semiconductor device comprising a second conducting type well region formed in a first conducting type silicon semiconductor substrate, wherein a MOS transistor of the load side is formed in the second conducting type well region, and a MOS transistor of the differential side is formed outside the second conducting type well region.

15. A semiconductor device comprising a second conducting type well region formed in a first conducting type silicon semiconductor substrate, wherein a MOS transistor of the differential side is formed in the second conducting type well, and a MOS transistor of the load side is formed outside the second conducting type well region.

16. A semiconductor device comprising a second conducting type well region and a third conducting type well region formed in a first conducting type silicon semiconductor substrate, wherein the MOS transistors of the differential side and the load side are formed in each well.

17. A method of manufacturing a semiconductor device in which a p-type transistor, which becomes a load transistor, and an n-type transistor, which becomes a differential transistor, formed in an n-type semiconductor region and in a p-type semiconductor region, respectively, on the surface of a semiconductor substrate, are integrated into a CMOS semiconductor device, said method comprising the steps of:
forming a gate insulating film on the surface of the semiconductor substrate;
forming a silicon thin film on the gate insulating film;
introducing an n-type impurity into the semiconductor region thin silicon thin film using an impurity diffusion furnace;
selectively etching the silicon thin film and of forming a gate electrode on the gate insulating film;
forming source and drain regions by ion injection of a p-type impurity into the surface of the n-type semiconductor region using the gate electrode as a mask;
forming source and drain regions by ion injection of the n-type impurity phosphorous into the surface of the p-type semiconductor region using the gate electrode as a mask; and
activating the source and drain regions by heat treatment at between 900 and 1050° C.

18. A method of manufacturing a semiconductor device in which a p-type transistor, which becomes a load transistor, and an n-type transistor, which becomes a differential transistor, formed in an n-type semiconductor region and in a p-type semiconductor region, respectively, on the surface of a semiconductor substrate, are integrated into a CMOS semiconductor device, said method comprising the steps of:
forming a gate insulating film on the surface of the semiconductor substrate;
forming a channel doped region by ion injection of an impurity into the surface of the n-type semiconductor region;
forming a channel doped region by ion injection of an impurity into the surface of the p-type semiconductor region;
forming a silicon thin film on the gate insulating film;
introducing an n-type impurity into the semiconductor region thin silicon thin film using an impurity diffusion furnace;
selectively etching the silicon thin film and of forming a gate electrode on the gate insulating film;
forming source and drain regions by ion injection of a p-type impurity into the surface of the n-type semiconductor region using the gate electrode as a mask;
forming source and drain regions by ion injection of the n-type impurity phosphorous into the surface of the p-type semiconductor region using the gate electrode as a mask; and
activating the source and drain regions by heat treatment at between 900 and 1050° C.

19. A method of manufacturing a semiconductor device, comprising formation of an n-type well layer and a p-type well layer in a semiconductor substrate using one mask, wherein the p-type well layer is formed after the n-type well layer is formed.

20. The method of manufacturing a semiconductor device according to claim 19, further comprising the steps of:
forming a silicon oxide film and a silicon nitride film in order on the semiconductor substrate;
selectively removing the silicon nitride film by a photo mask process, prescribing a region for the n-well layer;
ion injecting an n-type impurity into the semiconductor substrate;
forming a silicon oxide film in the n-well region where the silicon nitride film has been removed;
removing the silicon nitride film, prescribing a region for the p-well layer;
ion injecting a p-type impurity into the semiconductor substrate; and
heat treating the semiconductor substrate, diffusing and activating the impurity.
